(19) United States
(12) Patent Application Publication
(10) Pub. No.: US 2009/0027967 A1
(43) Pub. Date: Jan. 29, 2009

(54) NON-VOLATILE MEMORY DEVICE PROGRAMMING SELECTION TRANSISTOR AND METHOD OF PROGRAMMING THE SAME

(75) Inventor: Chang-hyun LEE, Suwon-si (KR)

Correspondence Address: VOLENTINE & WHITT PLLC, ONE FREEDOM SQUARE, 11951 FREEDOM DRIVE SUITE 1260, RESTON, VA, 20190, US

(73) Assignee: SAMSUNG ELECTRONICS CO., LTD., Suwon-si (KR)

(21) Appl. No.: 12/175,609

(22) Filed: Jul. 18, 2008

(30) Foreign Application Priority Data
Jul. 23, 2007 (KR) 10-2007-0073605

(51) Int. Cl. G11C 16/06

(52) U.S. Cl. 365/185.15; 365/185.18; 365/185.19; 365/185.28

(57) ABSTRACT

A memory system includes a flash memory device and a memory controller for controlling the flash memory device. The flash memory device includes a cell string and a selection transistor connected in series to the cell string. The cell string includes multiple series-connected memory cells. The selection transistor has the same structure as a memory cell of the series-connected memory cells, and is programmed through channel hot electron injection.

### CROSS-REFERENCE TO RELATED APPLICATIONS

A claim of priority is made to Korean Patent Application No. 10-2007-0073605, filed on Jul. 23, 2007, the subject matter of which is hereby incorporated by reference.

### BACKGROUND OF THE INVENTION

The present invention relates to a semiconductor memory device, and more particularly, to a programming selection transistor of a non-volatile memory device, such as a flash memory device, and a method of programming the same.

A semiconductor memory device is a memory device capable of storing data and reading stored data, as needed. A semiconductor memory device is typically either a random access memory (RAM) or a read only memory (ROM). The RAM is a volatile memory device which loses stored data when no power is applied. The ROM is a non-volatile memory device which retains stored data even when there is no power. Examples of RAM include dynamic RAM (DRAM) and static RAM (SRAM). Examples of ROM include programmable ROM (PROM), erasable PROM (EPROM), electrically EPROM (EEPROM), flash memory device, etc. A flash memory device is generally either a NAND flash memory device or a NOR flash memory device. The NAND type flash memory device has a higher degree of integration than the NOR flash memory device.

FIG. 1 is a block diagram of a typical NAND type flash memory device. Referring to FIG. 1, NAND flash memory device 10 includes a memory cell array 12, a row decoder 14 and a page buffer 16.

The memory cell array 12 includes multiple memory cells connected to word lines WL0 to WLₙ₋₁ and bit lines BL0 to BLₘ₋₁. The word lines WL0 to WLₙ₋₁ are driven by the row decoder 14 and the bit lines BL0 to BLₘ₋₁ are driven by the page buffer 16.

The memory cell array 12 includes multiple cell strings. Each of the cell strings includes a ground selection transistor, multiple memory cells and a string selection transistor, which all are connected in series. The ground selection transistor is connected to ground selection line GSL, the memory cells are connected to the word lines, and the string selection transistor is connected to string selection line SSL.

Referring to FIG. 1, each memory cell includes a control gate and a floating gate. In contrast, each selection transistor includes a metal oxide semiconductor (MOS) transistor without an additional floating gate. In the NAND flash memory device, additional processing is required to realize the selection transistors as MOS transistors. Additionally, a selection transistor is typically manufactured larger than the memory cell transistors in order to prevent leakage current. The typical NAND flash memory device therefore has various limitations due to the selection transistors and with respect to its manufacturing processes.

To overcome these limitations, the selection transistor can be designed to have the same structure as the typical memory cell. For example, a charge trap flash memory (CTF) uses a trap layer as a charge storage layer instead of a floating gate. In the CTF, a selection transistor can be designed to have the charge storage layer.

However, when the selection transistor includes a charge storage layer, the charge storage layer may be charged with electric charges. The electric charges change a threshold voltage of the selection transistor. That is, if electric charges are unintentionally charged in the charge storage layer of the selection transistor, a threshold voltage of the selection transistor changes. This causes malfunctions of the NAND flash memory device. Accordingly, when the selection transistor includes a charge storage layer, the threshold voltage of the selection transistors needs to be uniformly adjusted in order to normally drive the NAND flash memory.

### SUMMARY OF THE INVENTION

The present invention provides a non-volatile memory device which reduces threshold voltage distribution of a selection transistor, including a charge storage layer, and a method of programming the same.

An aspect of the present invention provides a method of programming a NAND flash memory device. The method includes programming a selection transistor through channel hot electron injection, and programming a selected memory cell through Fowler-Nordheim (F-N) tunneling.

In various embodiments, the selection transistor may include a charge storage layer. Also, the selection transistor may be a string selection transistor or a ground selection transistor.

In various embodiments, programming of the string selection transistor may include applying a pass voltage to a word line and a ground selection line, applying a bit line voltage to a bit line, and applying a program voltage to a string selection line. The bit line voltage may include a first voltage when the string selection transistor is programmed and a second voltage when the string selection transistor is not programmed. The program voltage applied to the string selection line may be incrementally increased. Also, the first voltage may be a voltage for program inhibiting the string selection transistor, and the second voltage is a voltage for programming the string selection transistor.

In various embodiments, programming of the ground selection transistor may include applying a pass voltage to a word line and a string selection line, applying a common source line voltage to a common source line, applying a bit line voltage to a bit line, and applying a program voltage to a ground selection line. The bit line voltage may include a third voltage when the ground selection transistor is programmed and a fourth voltage when the ground selection transistor is not programmed. The program voltage may be incrementally increased, and the common source line voltage may be incrementally increased. Also, the third voltage may be a voltage for program inhibiting the ground selection transistor, and the fourth voltage may be a voltage for programming the ground selection transistor.

Another aspect of the present invention provides a method of programming a NAND flash memory device. The method includes erasing a selection transistor of a selected memory block, loading data for programming the selection transistor into a page buffer, programming the selection transistor through channel hot electron injection, and programming a selected memory cell through F-N tunneling.

In various embodiments, the selection transistor may include a charge storage layer. Also, the selection transistor may have the same structure as a memory cell of the NAND flash memory device.

In various embodiments, erasing the selection transistor may be selectively performed. Also, erasing the selection transistor may include applying a ground voltage to a word line, applying a first voltage to a string selection line and a ground selection line, and applying an erase voltage to a bulk. The first voltage may be a voltage for inhibiting the selection transistor from being over erased.

Another aspect of the present invention provides a memory system including a NAND flash memory device and a memory controller for controlling the NAND flash memory device. The NAND flash memory device includes a cell string including series-connected memory cells, and a selection transistor connected in series to the cell string and having the same structure as a memory cell of the series-connected memory cells. The selection transistor is programmed through channel hot electron injection. The NAND flash memory device and the memory controller may be integrated into one memory card.

Yet another aspect of the present invention provides a method of programming a non-volatile memory device. The method includes programming a selection transistor through channel hot electron injection, and programming a selected memory cell through F-N tunneling.

In various embodiments, the selection transistor may include a charge storage layer. Also, the non-volatile memory device may include a NOR memory device including a memory cell, where the memory cell is programmed through F-N tunneling.

### BRIEF DESCRIPTION OF THE FIGURES

The accompanying figures are included to provide a further understanding of the present invention, and are incorporated in and constitute a part of this specification. The embodiments of the present invention will be described with reference to the attached drawings, in which:

FIG. 1 is a block diagram illustrating a typical NAND flash memory device;

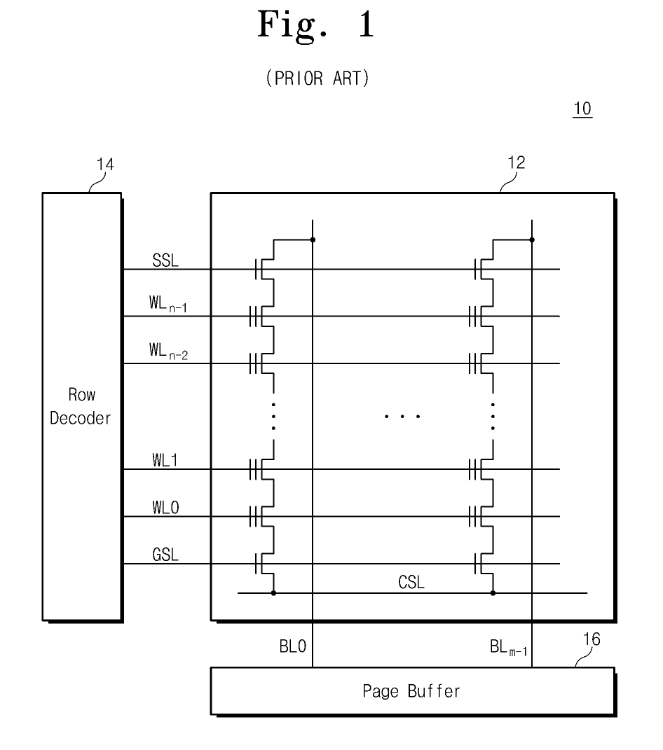

FIG. 2 is a sectional view illustrating a cell string structure of a NAND flash memory, according to an exemplary embodiment of the present invention;

FIG. 3 is a graph illustrating threshold voltage distribution of a selection transistor;

FIG. 4 is a block diagram illustrating a NAND flash memory device, according to an exemplary embodiment of the present invention;

FIG. 5 is a sectional view illustrating a program bias condition of the string selection transistor SST of FIG. 4, according to an exemplary embodiment of the present invention;

FIG. 6 is a graph and a table illustrating a method of programming a string selection transistor by incrementally increasing a voltage of the string selection line, according to an exemplary embodiment of the present invention;

FIG. 7 is a graph and a table illustrating a method of programming a string selection transistor by incrementally increasing a voltage of a bit line, according to an exemplary embodiment of the present invention;

FIG. 8 is a sectional view illustrating a program bias condition of a ground selection transistor GST of FIG. 4, according to an exemplary embodiment of the present invention;

FIG. 9 is a graph and a table illustrating a method of programming a ground selection transistor by incrementally increasing a voltage of the ground selection line, according to an exemplary embodiment of the present invention;

FIG. 10 is a graph and a table illustrating a method of programming a ground selection transistor by incrementally increasing a voltage of a common source line, according to an exemplary embodiment of the present invention;

FIG. 11 is a flowchart illustrating a method of programming the selection transistors of the NAND flash memory device of FIG. 4, according to an exemplary embodiment of the present invention;

FIG. 12 is a block diagram illustrating a memory card with a flash memory device of the present invention, according to an exemplary embodiment of the present invention; and

FIG. 13 is a block diagram illustrating a memory system including a flash memory device, according to an exemplary embodiment of the present invention.

### DETAILED DESCRIPTION OF THE EMBODIMENTS

Embodiments of the present invention include methods of reducing threshold voltage distribution of a selection transistor by utilizing channel hot electron injection to program the selection transistor including a charge storage layer.

The present invention will now be described more fully with reference to the accompanying drawings, in which exemplary embodiments of the invention are shown. The invention, however, may be embodied in various different forms, and should not be construed as being limited only to the illustrated embodiments. Rather, these embodiments are provided as examples, to convey the concept of the invention to one skilled in the art. Accordingly, known processes, elements, and techniques are not described with respect to some of the embodiments of the present invention. Throughout the drawings and written description, like reference numerals will be used to refer to like or similar elements.

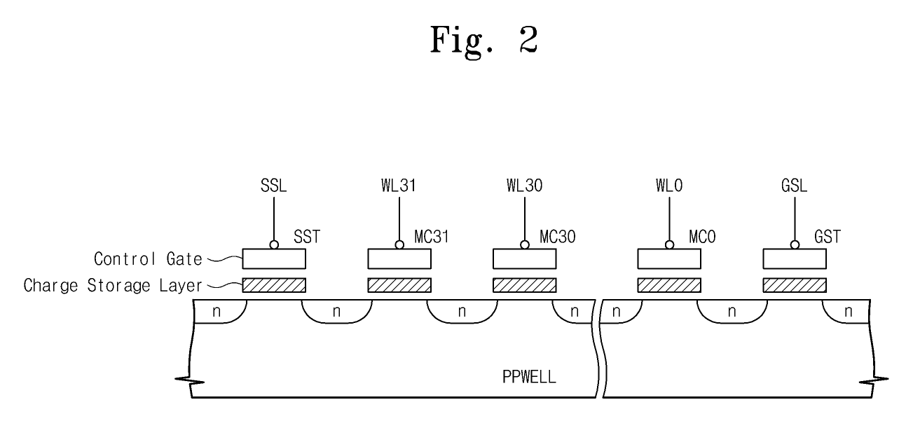

FIG. 2 is a sectional view illustrating a cell string structure of a NAND flash memory, according to an exemplary embodiment of the present invention. Referring to FIG. 2, a cell string includes a string selection transistor SST, memory cells MC0 to MC31, and a ground selection transistor GST. The selection transistors SST and GST have the same structure as the memory cells MC0 to MC31. That is, the selection transistors SST and GST include a floating gate or a charge trap as a charge storage layer.

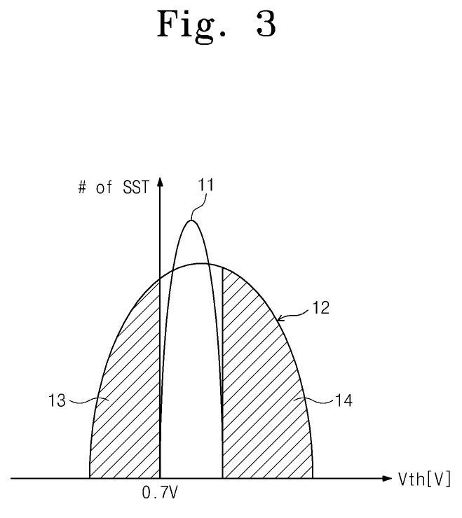

FIG. 3 is a graph illustrating threshold voltage distribution of a selection transistor. Referring to FIG. 3, reference number 11 represents normal threshold voltage distribution of a selection transistor, and reference number 12 represents abnormal threshold voltage distribution. Here, normal threshold voltage means that threshold voltage distribution of the selection transistor allows a flash memory device to operate normally. The normal threshold voltage of the illustrative selection transistor shown in FIG. 3 is about 0.7 V.

Reference number 13 illustrates a case in which the threshold voltage distribution of the selection transistor is lower than the normal threshold voltage distribution 11. If a threshold voltage of the selection transistor is low, program inhibit cells may be unintentionally programmed. That is, when boosting a channel for program inhibit, electric charges of the boosted channel may leak through the string selection transistor SST or the ground selection transistor GST. Accordingly, the program inhibit characteristics are drastically deteriorated.

Reference number 14 illustrates a case in which the threshold voltage distribution of the selection transistor is higher than the normal threshold voltage distribution 11. If a threshold voltage of the selection transistor is high, the selection transistor may not be normally turned on.

For example, assuming that a power supply voltage Vcc is applied to a gate and a drain of a selection transistor for program inhibit, if the selection transistor is not normally turned on, a channel voltage of the program inhibit cell string does not rise. Additionally, a channel of a cell string to be programmed enters a floating state, so that a normal program operation may not be performed. Errors may occur while reading stored data in a cell. If the selection transistor is not turned on, data of a memory cell may not be normally read due to a high resistance.

In other words, when the threshold voltage distribution of the selection transistor is the abnormal threshold voltage distribution 12, the NAND flash memory device may malfunction during program and read operations. For example, a program inhibit cell may be programmed, a program cell may not be programmed, or stored data may not be read. To avoid these issues, embodiments of the present invention enable the threshold voltage distribution of the selection transistor to be like the normal threshold voltage distribution 11 through a channel hot electron injection method.

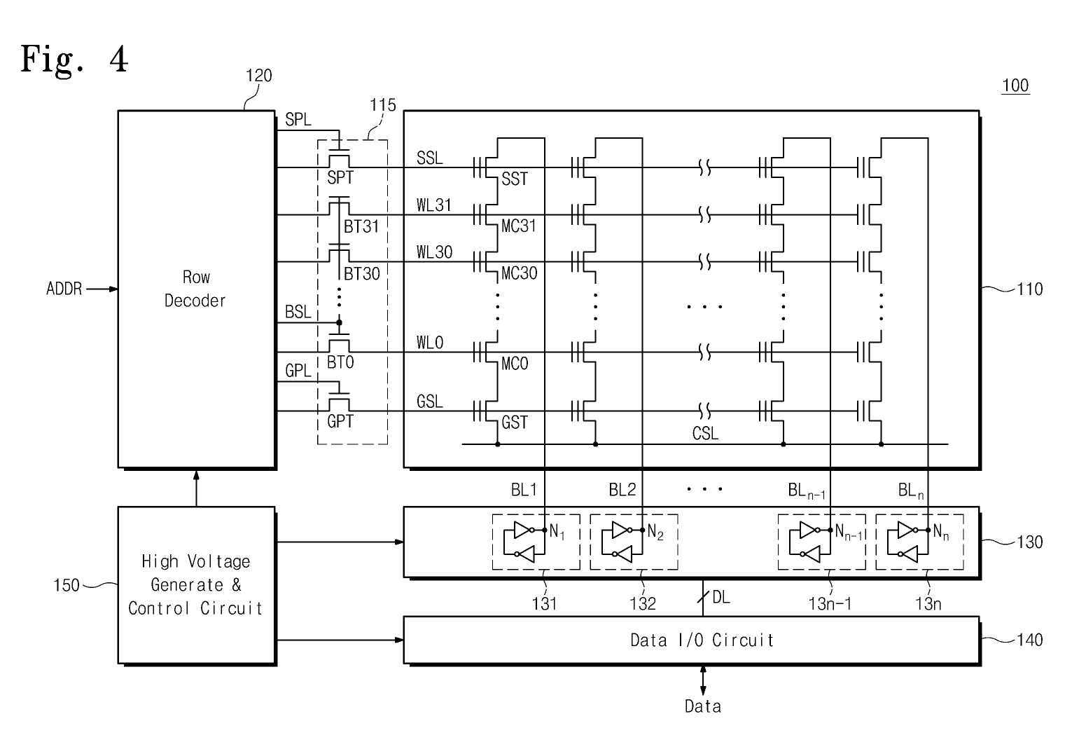

FIG. 4 is a block diagram of a NAND flash memory device 100, according to an exemplary embodiment of the present invention. Referring to FIG. 4, NAND flash memory device 100 includes a cell array 110, a block selection circuit 115, a row decoder 120, a page buffer 130, a data I/O circuit 140, and a high voltage generate & control circuit 150.

The cell array 110 includes multiple memory blocks, although only one memory block is illustrated in detail in FIG. 4, for purposes of discussion. Each memory block includes multiple pages. Each page includes multiple memory cells MC0 to MC31. In the NAND flash memory device 100, the memory block is the unit of erasing, and the page is the unit of reading or programming.

Each memory block also includes multiple cell strings. Each cell string includes a ground selection transistor GST, memory cells MC0 to MC31, and a string selection transistor SST. The ground selection transistor GST is connected to a ground selection line GSL. The memory cells MC0 to MC31 are connected to word lines WL0 to WL31, respectively. The string selection transistor SST is connected to a string selection line SSL. The cell string is connected between the corresponding bit line (e.g., BL1) and the common source line CSL.

Each memory cell includes a control gate and a charge storage layer. The charge storage layer includes a charge trap or a floating gate.

The selection transistors GST and SST have the same structure as each memory cell. That is, the selection transistors GST and SST have a control gate and a charge storage layer. However, according to various exemplary embodiments, each of the selection transistors GST and SST has a programming method different from that of the memory cells. Each memory cell is programmed through a Fowler-Nordheim (F-N) tunneling method, but the each of the selection transistors GST and SST is programmed through a channel hot electron injection method, described in more detail below.

Referring to FIG. 4, the block selection circuit 115 is connected between the cell array 110 and the row decoder 120. The block selection circuit 115 includes a ground pass transistor GPT, block transistors BT0 to BT31 and a string pass transistor SPT.

A ground pass line GPL is connected to a gate of the ground pass transistor GPT, a row decoder 120 is connected to a drain of the ground pass transistor GPT, and a ground selection line GSL is connected to a source of the ground pass transistor GPT. The ground pass transistor GPT is turned on or off in accordance with a voltage level of the ground pass line GPL. It is understood that, throughout the disclosure, the connections of drains and sources may be interchangeable, for example, depending on transistor type, without departing from the spirit and scope of the disclosure.

Block transistors BT0 to BT31 are respectively connected between the word lines WL0 to WL31 and the row decoder 120. A block selection line BSL is connected to gates of the block transistors BT0 to BT31. The block selection line BSL is driven in response to a block address provided to the row decoder 120. The block transistors BT0 to BT31 may include high voltage transistors having high durability for voltages higher than power supply voltage Vcc.

The string pass line SPL is connected to a gate of the string pass transistor SPT. A drain of the string pass transistor SPT is connected to the row decoder 120, and a source is connected to the string selection line SSL. The string pass transistor SPT is turned on or off in accordance with a voltage level of the string pass line SPL.

Referring to FIG. 4, the row decoder 120 is connected to the memory cell array 110 through the block selection circuit 115. The row decoder 120 operates under control of the high voltage generate & control circuit 150. The row decoder 120 receives an address, and selects a word line, accordingly. For example, the row decoder 120 receives a block address and drives the block selection line BSL, and also receives a page address and drives a word line.

The row decoder 120 controls the ground pass transistor GPT, the block transistors BT0 to BT31, and the string pass transistor SPT. Additionally, voltages applied to the ground selection line GSL, the word lines WL0 to WL31, and the string selection line SSL pass through the ground pass transistor GPT, the block transistors BT0 to BT31, and the string pass transistor SPT, respectively.

The page buffer 130 is connected between the memory cell array 110 and the data I/O circuit 140. The page buffer 130 is connected to the memory cell array 110 through the bit lines BL1 to BL31, and is connected to the data I/O circuit 140 through data line DL. The page buffer 130 is controlled by the high voltage generate & control circuit 150. The page buffer 140 stores data to be programmed in the cell array 110, or stores data read from the cell array 110.

The page buffer 130 includes multiple page buffer units 131 to 13n. Each of the page buffer units 131 to 13n includes a latch. The page buffer 130 temporarily stores data to be programmed or read data in the latches. Each latch generally includes two inverters and one of sensing nodes N1 to Nn, which are respectively connected to the bit lines BL1 to BLn.

When programming a memory cell, a voltage level of the sensing node has a ground voltage of about 0 V. In comparison, when programming a selection transistor, a voltage level of the sensing node has a program voltage. The reason is that the memory cell is programmed by utilizing F-N tunneling and the selection transistor is programmed by utilizing channel hot electron injection. This will be described in more detail below.

The data I/O circuit 140 is connected to the page buffer units 131 to 13n through the data line DL. The data I/O circuit 140 transmits data input from the exterior into the page buffer 130, or outputs data provided from the page buffer 130. The data I/O circuit 140 is controlled by the high voltage generate & control circuit 150.

The high voltage generate & control circuit 150 controls general operations of the NAND flash memory device 100. The high voltage generate & control circuit 150 controls the row decoder 120, the page buffer 130, and the data I/O circuit 140. The high voltage generate & control circuit 150 generates a program voltage during a program operation, a read voltage during a read operation, and an erase voltage during an erase operation.

Referring to FIG. 4, the NAND flash memory device 100 includes selection transistors having the same structure as the memory cells. According to various embodiments of the present invention, the memory cells are programmed by utilizing F-N tunneling, and the selection transistors are programmed by utilizing channel hot electron injection. Because the selection transistors are programmed by utilizing channel hot electron injection, the corresponding threshold voltage distributions of the selection transistors can be reduced.

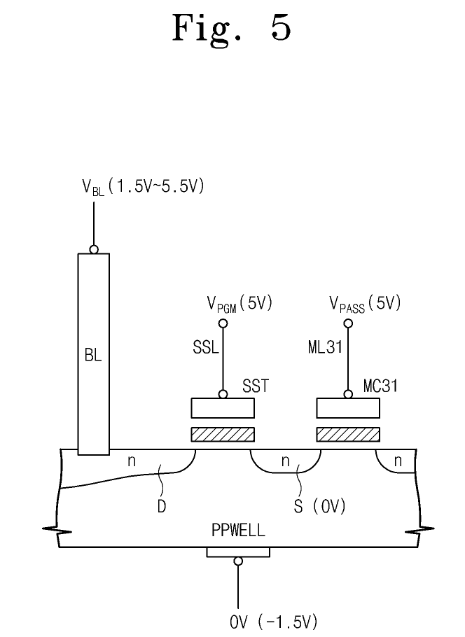

FIG. 5 is a sectional view for illustrating a program bias condition of a string selection transistor SST of FIG. 4, according to an exemplary embodiment of the present invention. For purposes of simplifying discussion, only memory cell MC31, adjacent to the string selection transistor SST, and an exemplary bit line BL are illustrated in FIG. 5.

Referring to FIG. 5, a pass voltage V_{PASS} (e.g., about 5 V) is applied to the word lines WL0 to WL31 of the memory cells MC0 to MC31 of FIG. 4. A pass voltage V_{PASS} is also applied to the ground selection line GSL of FIG. 4, and the common source line CSL is grounded. Under this bias condition, a ground voltage (e.g., indicated as 0 V) is applied to the source S of the string selection transistor SST.

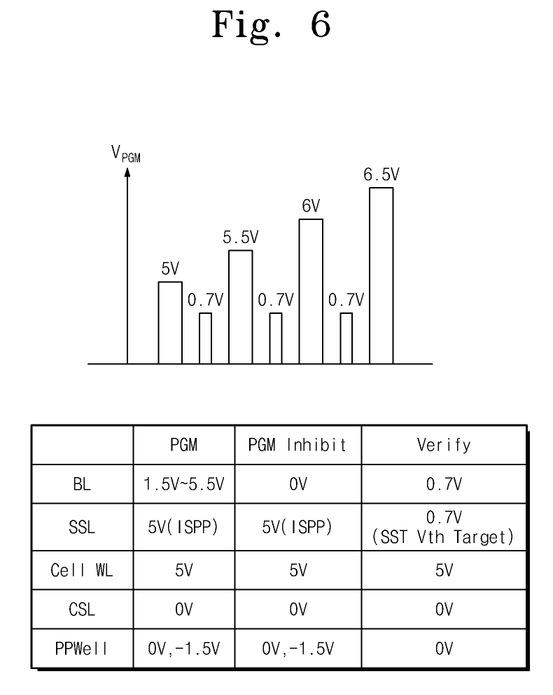

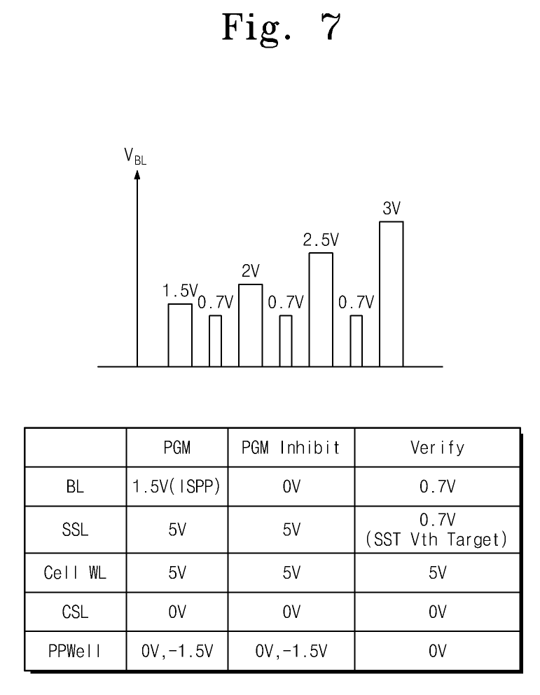

A bit line voltage V_{BL} (e.g., about 1.5 V to about 5.5 V) is applied to the bit line BL. Then, a program voltage V_{PGM} (e.g., about 5 V) is applied to the gate of the string selection transistor SST. In various embodiments, the gate voltage or the bit line voltage of the string selection transistor SST may be incrementally increased in subsequent program operations. This will be described in more detail below with reference to FIGS. 6 and 7.

Under this bias condition, the string selection transistor SST is programmed by utilizing channel hot electron injection. About 0 V or about −1.5 V is applied to bulk PPWELL. The negative voltage may be applied to the bulk PPWELL in order to increase an electric field between the gate and the channel of the string selection transistor SST.

FIG. 6 is a graph and a table illustrating a method of programming a string selection transistor by incrementally increasing a voltage of the string selection line, according to an exemplary embodiment of the present invention.

First, referring to the first column of the table in FIG. 6, the bit line voltage V_{BL} is applied to the bit line BL. The bit line voltage V_{BL} is a voltage (e.g., about 1.5 V to about 5.5 V) high enough to allow the string selection transistor SST to be programmed through channel hot electron injection. The pass voltage (e.g., about 5 V) is applied to each word line WL. The program voltage V_{PGM} (e.g., about 5 V) is applied to the string selection line SSL of FIG. 4. At this point, the string selection transistors SST sharing the string selection line SSL are simultaneously programmed. Additionally, the program voltage V_{PGM} may be incrementally increased. About 0 V or about −1.5 V is applied to the bulk PPWELL. The reason for applying the negative voltage to the bulk PPWELL is to increase an electric field between a gate and a channel of the string selection transistor SST.

All the string selection transistors SST must be programmed above a threshold voltage (e.g., about 0.7 V) of a predetermined level. The threshold voltage of the predetermined level may be referred to as a verify voltage.

Next, a program verify operation is performed. At this point, a predetermined voltage (e.g., about 0.7 V) is applied to the bit line BL. A verify voltage (e.g., about 0.7 V) is applied to the string selection line SSL. A pass voltage V_{PASS} (e.g., about 5 V) is applied to each word line WL.

When the program verify operation indicates a program verify result, the program operation for the program passed string selection transistor SST will not be repeated. At this point, a program inhibit voltage (here, V_{BL}=V_{IHB}) is applied to the bit line BL of the program passed string selection transistor SST. The program inhibit voltage V_{IHB} is a voltage (e.g., about 0 V) sufficiently low not to allow the string selection transistor SST to be programmed through channel hot electron injection.

The program voltage V_{PGM} or the program inhibit voltage V_{IHB} of the string selection transistor SST is controlled by a latch of the page buffer 130 of FIG. 4. That is, when the program verify result is program pass, a sensing node (e.g., N1) of a latch is changed to a program inhibit voltage V_{IHB} of about 0 V. This is the opposite result from the method of programming a memory cell. In the memory cell, the sensing node (e.g., N1) of the latch is changed to a power supply voltage Vcc when the program verify result is program pass.

When the program verify result indicates a program failed string selection transistor SST, the program voltage V_{PGM} is increased, e.g., by a predetermined increment, and the program operation is repeated. The program inhibit voltage is not applied to the bit line BL. In the example shown in FIG. 6, the program voltage V_{PGM} may be increased, if necessary, from about 5 V to about 6.5 V by 0.5 V increments. By repeating these operations, each of the string selection transistors SST are able to have a normal threshold voltage distribution (e.g., threshold voltage distribution 11 of FIG. 3).

FIG. 7 is a graph and a table illustrating a method of programming a string selection transistor by incrementally increasing a voltage of a bit line BL, according to an exemplary embodiment of the present invention.

First, a bit line voltage V_{BL} of about 1.5 V is applied to all the bit lines BL1 to BLn, shown in FIG. 4. A pass voltage (e.g., about 5 V) is applied to each word line WL. A program voltage V_{PGM} (e.g., about 5 V) is applied to the string selection line SSL of FIG. 4. About 0 V or about −1.5 V is applied to the bulk PPWELL. The reason for applying the negative voltage to the bulk PPWELL is to increase an electric field between a gate and a channel of the string selection transistor SST. At this point, the threshold voltage of each string selection transistor SST rises.

Next, a program verify operation is performed. At this point, a predetermined voltage (e.g., about 0.7 V) is applied to the bit line BL. A verify voltage (e.g., about 0.7 V) is applied to the string selection line SSL. A pass voltage V_{PASS} (e.g., about 5 V) is applied to each word line WL.

When the program verify result is program pass, program operations for the program passed string selection transistor SST will not be repeated. A program inhibit voltage V_{IHB} (about 0 V) is applied to the bit line BL connected to the program passed string selection transistor SST. When the program verify result is program failed, the bit line voltage V_{BL} applied to the bit line BL connected to the program failed string selection transistor SST is increased incrementally, and then the program operation is repeated. In the example shown in FIG. 7, the bit line voltage V_{BL} may be increased, if necessary, from about 1.5 V to about 3 V by 0.5 V increments. By repeating these operations, each of the string selection transistors SST are able to have a normal threshold voltage distribution (e.g., threshold voltage distribution 11 of FIG. 3).

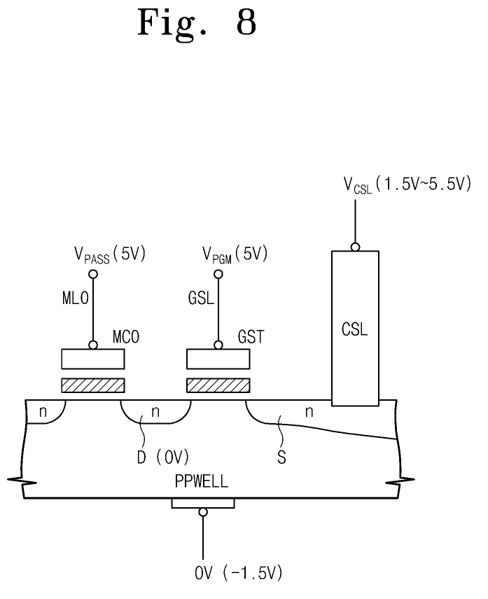

FIG. 8 is a sectional view for illustrating a program bias condition of the ground selection transistor GST of FIG. 4, according to an exemplary embodiment of the present invention. For purposes of simplifying discussion, only memory cell MC0, adjacent to the ground selection transistor GST, and the common source line CSL are illustrated in FIG. 8 for describing the bias condition.

Referring to FIG. 8, a pass voltage V_{PASS} (e.g., about 5 V) is applied to the word lines WL0 to WL31 of the memory cells MC0 to MC31 of FIG. 4. A pass voltage V_{PASS} is applied to the string selection line SSL of FIG. 4, and the bit lines BL0 to BLn of FIG. 4 are grounded. Under this bias condition, a ground voltage (e.g., indicated as 0 V) is applied to the drain D of the ground selection transistor GST.

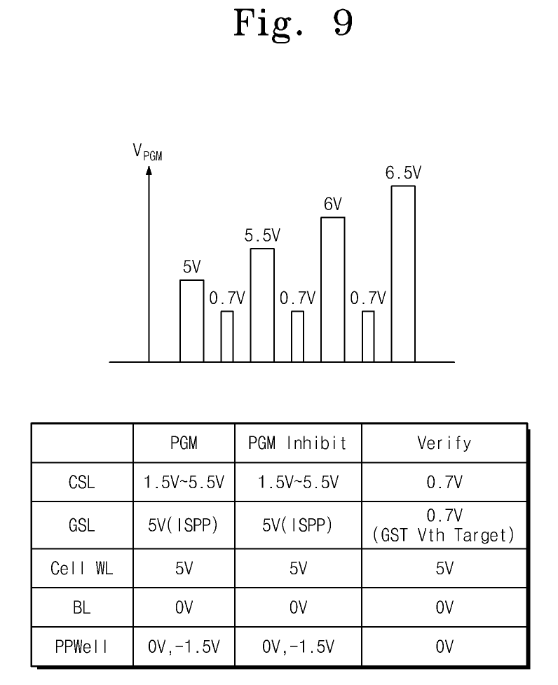

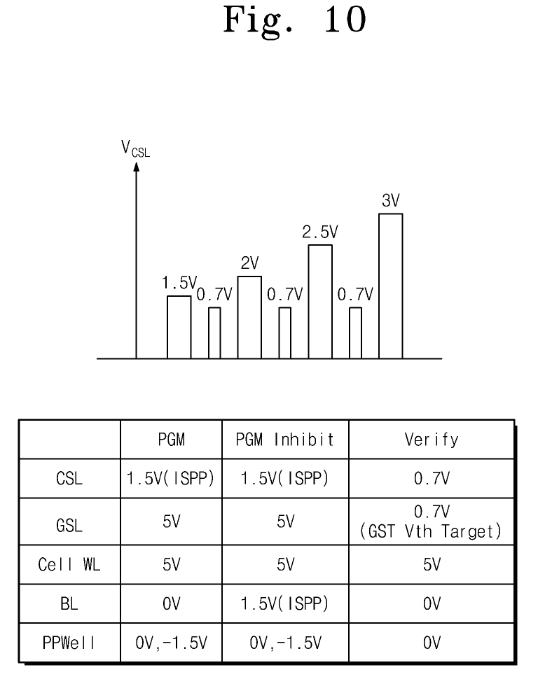

A common source line voltage V_{CSL} (e.g., about 1.5 V to about 5.5 V) is applied to the common source line CSL. Then, a program voltage V_{PGM} (e.g., about 5 V) is applied to a gate of the ground selection transistor GST. In various embodiments, the gate voltage or the common source line voltage of the ground selection transistor GST may be incrementally increased in subsequent program operations. This will be described in more detail below with reference to FIGS. 9 and 10.

Under this bias condition, the ground selection transistor GST is programmed through channel hot electron injection. About 0 V or about −1.5 V is applied to a bulk PPWELL. The negative voltage may be applied to the bulk PPWELL to increase an electric field between a gate and a channel of the ground selection transistor GST.

FIG. 9 is a graph and a table illustrating a method of programming a ground selection transistor by incrementally increasing a voltage of the ground selection line, according to an exemplary embodiment of the present invention.

First, referring to the first column of the table in FIG. 9, a common source line voltage V_{CSL} (e.g., about 1.5 V to about 5.5 V) is applied to the common source line CSL. Then, a pass voltage V_{PASS} (e.g., about 5 V) is applied to each word line WL. A ground voltage is applied to the bit line BL. A program voltage V_{PGM} (e.g., about 5 V) is applied to the ground selection line GSL of FIG. 4. At this point, the ground selection transistors GST sharing the ground selection line GSL are simultaneously programmed. About 0 V or about −1.5 V is applied to the bulk PPWELL. The reason for applying the negative voltage to the bulk PPWELL is to increase an electric field between a gate and a channel of the ground selection transistor GST.

All the ground selection transistors GST must be programmed above a threshold voltage (e.g., about 0.7 V) of a predetermined level. The threshold voltage of the predetermined level is called a verify voltage.

Next, a program verify operation is performed. At this point, a predetermined voltage (e.g., about 0.7 V) is applied to the common source line CSL. A verify voltage (e.g., about 0.7 V) is applied to the ground selection line GSL. A pass voltage V_{PASS} (e.g., about 5 V) is applied to each word line WL, and a ground voltage is applied to the bit line BL.

When the program verify operation indicates a program verify result, a program operation for the program passed ground selection transistor GST is not repeated. At this point, a program inhibit voltage (here, V_{BL}=V_{IHB}) is applied to the bit line BL of the program passed ground selection transistor GST. The program inhibit voltage V_{IHB} is a sufficiently low voltage (e.g., about 0 V) not to allow the ground selection transistor GST to be programmed through channel hot electron injection.

When the program verify operation indicates a program failed ground selection transistor GST, the program voltage V_{PGM} is increased, e.g., by a predetermined increment, and the program operation is performed again. In the example shown in FIG. 9, the program voltage V_{PGM} may be increased, if necessary, from about 5 V to about 6.5 V by 0.5 V increments. Repeating this operation allows each ground selection transistor GST to have a normal threshold voltage distribution (e.g., normal threshold voltage distribution 11 of FIG. 3).

FIG. 10 is a graph and a table illustrating a method of programming a ground selection transistor by incrementally increasing a voltage of a common source line, according to an exemplary embodiment of the present invention.

First, a common source line voltage V_{CSL} of about 1.5 V is applied to the common source line CSL of FIG. 4. A pass voltage (e.g., about 5 V) is applied to each word line WL and a ground voltage is applied to the bit line BL. A program voltage V_{PGM} (e.g., about 5 V) is applied to the ground selection line GSL of FIG. 4. At this point, a threshold voltage of each of the ground selection transistors GST is increased. About 0 V or about −1.5 V is applied to the bulk PPWELL. The reason for applying the negative voltage to the bulk PPWELL is to increase an electric field between a gate and a channel of the ground selection transistor GST.

Next, a program verify operation is performed. A predetermined voltage (e.g., about 0.7 V) is applied to the common source line CSL. A verify voltage (e.g., about 0.7 V) is applied to the ground selection line GSL. A pass voltage V_{PASS} (e.g., about 5 V) is applied to each word line WL. A ground voltage is applied to the bit line BL.

When the program verify operation indicates a program verify result, a program operation for the program passed ground selection transistor GST will not be repeated. A program inhibit voltage V_{IHB} (about 1.5 V) is applied to the bit line BL connected to the program passed ground selection transistor GST. The program inhibit voltage V_{IHB} may be incrementally increased as the common source line voltage V_{CSL} is incrementally increased, as discussed below.

When the program verify operation indicates a program failed ground selection transistor GST, the common source line voltage V_{CSL} is increased, and then the program operation is performed again. In the example shown in FIG. 10, the common source line voltage V_{CSL} may be increased, if necessary, from about 1.5 V to about 3 V by 0.5 V increments. Repeating this operation allows each ground selection transistor GST to have a normal threshold voltage distribution (e.g., normal threshold voltage distribution 11 of FIG. 3).

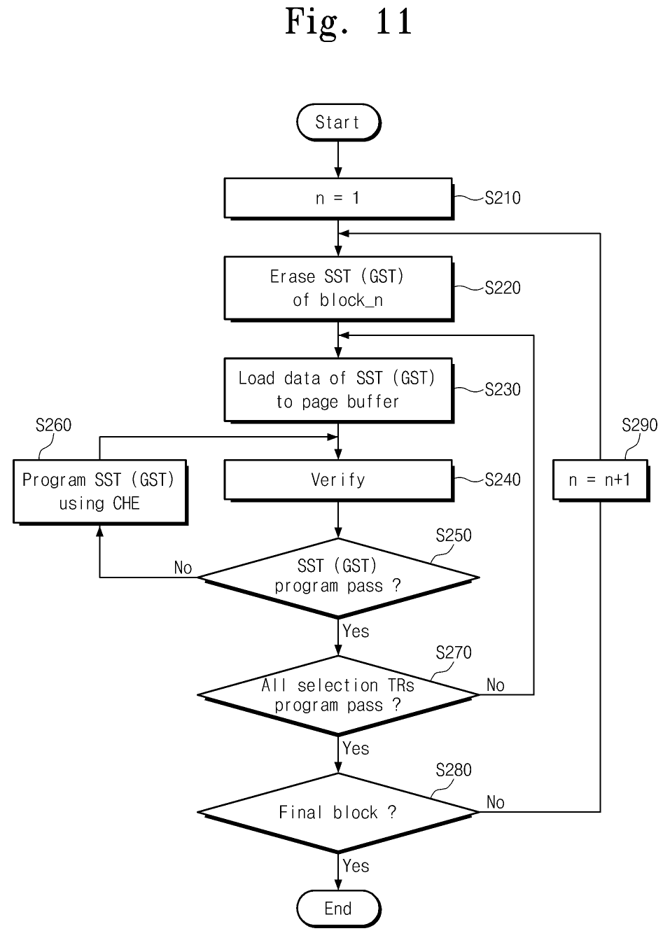

FIG. 11 is a flowchart illustrating a method of programming the selection transistors of the NAND flash memory device of FIG. 4, according to an exemplary embodiment of the present invention. The method will be described with reference to FIGS. 4 and 11.

In operation S210, a memory block is selected. As illustrated in FIG. 4, the memory block may be selected by a block address. The block address are sequentially selected, beginning with a first block address (n=1), indicated in operation S210, to a final block address.

In operation S220, the selection transistor SST or GST of the selected memory block (block_n) is erased. At this point, the memory cells are not erased, but only the selection transistors are erased. To inhibit the memory cells from being erased, the block transistors BT0 to BT31 of FIG. 4, respectively connected to the word lines WL0 to WL31, are turned off. Gates of the memory cells enter a floating state. Accordingly, even when an erase voltage (e.g., about 20 V) is applied to the bulk PPWELL, the memory cells are not erased.

To erase the selection transistor SST or GST, a predetermined voltage (e.g., about 0 V) or a positive voltage (e.g., about 10 V) is applied to the selection line SSL or GSL. The positive voltage may be applied to the selection line SSL or GSL, if necessary, to prevent the selection transistor from being over erased.

According to another exemplary embodiment, the memory cells and the selection transistors may be simultaneously erased. When all of the selection transistors are erased, a lower voltage (e.g., about 0 V) is applied to the word lines WL0 to WL31. Then, a positive voltage (e.g., about 10 V) is applied to the string selection line SSL and the ground selection line GSL. Accordingly, when an erase voltage (e.g., about 20 V) is applied to the bulk PPWELL, all of the selection transistors are erased.

Operation S220 may be omitted under certain circumstances. For example, if a threshold voltage of the selection transistor SST or GST is not distributed over a region of the threshold voltage distribution 14 of FIG. 3, operation S220 may be omitted.

In operation S230, data for programming the selection transistor are stored in the page buffer 130 of FIG. 4. The programming data may be input from the outside through the data I/O circuit 140 of FIG. 4. Additionally, the programming data may be internally set up by controlling a sensing node of the page buffer 130. For example, all of the sensing nodes of the page buffer 130 may be set up to have a power supply voltage Vcc.

In operation S240, a verify operation of the selection transistor SST or GST is performed. According to the verify operation result, if the selection transistor SST or GST is program fail, a power supply voltage Vcc is stored in the page buffer 130, and the process advances to operation S260. According to the verify operation result, if the selection transistor SST or GST is program pass, a ground voltage is stored in the page buffer 130, and the process advances to operation S270.

In operation S260, the selection transistor SST or GST is programmed through channel hot electron injection. At this point, a threshold voltage of the selection transistor SST or GST is increased and operation 240 is repeated for program verification. Based on the program verification result, as shown in operation S250, when there is a program failed selection transistor, a program voltage V_{PGM} is increased and a program operation is performed again in operation S260.

When the selection transistor is a string selection transistor SST, the bit line voltage V_{BL} may be increased and the program operation performed. When the selection transistor is a ground selection transistor GST, the common source line voltage V_{CSL} may be increased and the program operation performed.

In operation S270, it is determined whether all of the selection transistors have been successfully programmed. When only the string selection transistors SST are programmed, the process returns to operation S230 for programming the ground selection transistors GST. Likewise, when only the ground selection transistors GST are programmed, the process returns to operation S230 for programming the string selection transistors SST.

In operation S280, it is determined whether the selection transistors of all the memory blocks have been programmed. If there are still memory blocks to be programmed, the process advances to operation S290, which increments n by 1, indicating the next memory block to be programmed. Operations S220 to S280 are then repeated for the next memory block. When it is determined in operation S280 that there are no more memory blocks to be programmed, the program operation is terminated.

According to the above-described exemplary embodiments, when a selection transistor in a NAND flash memory device includes a charge storage layer, the selected transistor is programmed through channel hot electron injection. However, selection transistors including charge storage layers in other types of memory devices can be programmed through channel hot electron injection, as well.

For example, in a case of a memory device including an electrically erasable and programmable ROM (EEPROM) arranged in a 2T-FN-NOR type, two transistors constitute one memory cell. Each memory cell has a floating gate and a control gate and is programmed through F-N tunneling. In comparison, a selection transistor includes a MOS transistor without an additional floating gate. If the selection transistor in the EEPROM of the 2T-FN-NOR type has a floating gate or a charge trap layer, the selection transistor may be programmed through channel hot electron injection, according to the embodiments of the present invention.

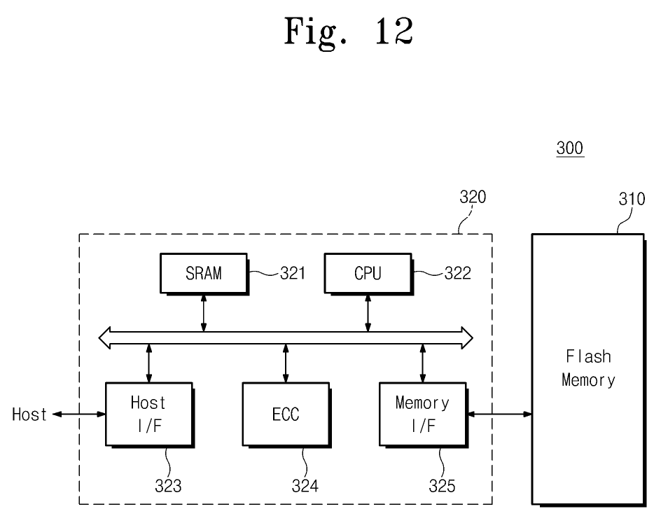

FIG. 12 is a block diagram of a memory card with a flash memory device, according to exemplary embodiments of the present invention. Referring to FIG. 12, a memory card 300 for supporting high capacity data storage includes a flash memory device 310 according to exemplary embodiments of the present invention. The memory card 300 includes a memory controller 320 controlling general data exchanges between a Host and the flash memory device 310.

SRAM 321 is used as an operation memory of central processing unit (CPU) 322. A host I/F 323 includes the data exchange protocol of the Host connected to the memory card 300. An error correction (ECC) block 324 detects and corrects errors in data read from the flash memory device 310. A memory I/F 325 interfaces with the flash memory 310.

The CPU 322 performs general operations for data exchange of the memory controller 320. Although not illustrated in the drawing, it is apparent to those skilled in the art that the memory card 300 may further include ROM (not shown) for storing code data, e.g., in order to interface with the Host.

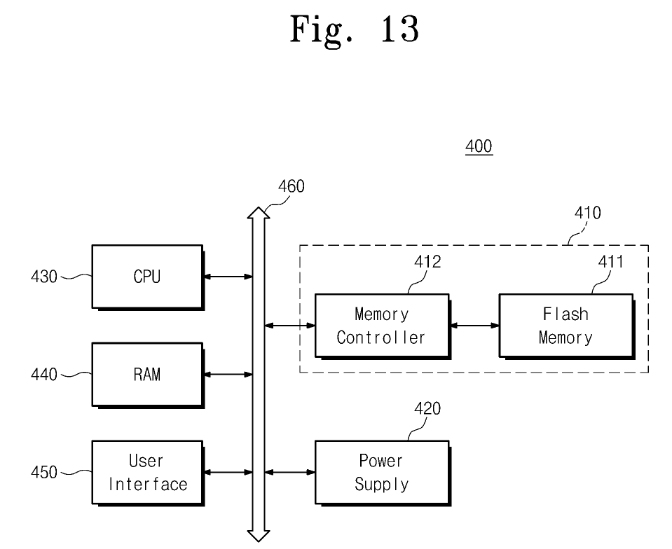

FIG. 13 is a block diagram of a memory system including a flash memory device, according to exemplary embodiments the present invention. Referring to FIG. 13, a memory system 400 includes a flash memory system 410, a power supply 420, a CPU 430, a RAM 440, a user interface 450, and a system bus 460.

The flash memory system 410 includes a memory controller 412 and a flash memory device 411. The flash memory system 410 is electrically connected to the power supply 420, the CPU 430, the RAM 440, and the user interface 450 through the system bus 460. The flash memory device 411 stores data, e.g., provided through the user interface 450 and processed by the CPU 430, according to a control of the memory controller 412.

If the flash memory system 410 is mounted as a solid state disk (SSD), for example, a booting speed of the system is improved. Although not illustrated in the drawings, it is apparent to those skilled in the art that the system may further include an application chipset, a camera image processor, etc.

As described above, the present invention provides a method of biasing bit lines, ground selection lines, word lines, and string selection lines in a memory cell array by means of a predetermined voltage. The selection transistor SST or GST is programmed through channel hot electron injection. Threshold voltage distribution of the programmed selection transistor SST or GST is adjusted to a normal distribution. Consequently, even when the selection transistor SST or GST has a charges storage layer, the flash memory device operates normally.

According to various exemplary embodiments of the present invention, the method of programming selection transistors through channel hot electron injection reduces threshold voltage distributions of the selection transistors.

In the case of a NAND flash memory using a floating gate type transistor, the programming method of embodiments of the present invention prevents malfunctions of the memory when the selection transistor includes a floating gate. That is, the programming method can omit a process for fabricating each selection transistor to have a MOS transistor structure.

In a case of a NAND flash memory using a charge trap type transistor, the programming method of embodiments of the present invention reduces threshold voltage distribution, such that malfunctions of the selection transistor can be prevented. Therefore, yields and reliability of the NAND flash memory are improved.

While the present invention has been described with reference to exemplary embodiments, it will be apparent to those skilled in the art that various changes and modifications may be made without departing from the spirit and scope of the present invention. Therefore, it should be understood that the above embodiments are not limiting, but illustrative.

What is claimed is:

1. A method of programming a NAND flash memory device, the method comprising:
programming a selection transistor through channel hot electron injection; and
programming a selected memory cell through Fowler-Nordheim (F-N) tunneling.

2. The method of claim 1, wherein the selection transistor comprises a charge storage layer.

3. The method of claim 1, wherein the selection transistor comprises one of a string selection transistor or a ground selection transistor.

4. The method of claim 3, wherein programming of the string selection transistor comprises:
applying a pass voltage to a word line and a ground selection line;
applying a bit line voltage to a bit line; and
applying a program voltage to a string selection line,
wherein the bit line voltage comprises a first voltage when the string selection transistor is programmed and a second voltage when the string selection transistor is not programmed.

5. The method of claim 4, wherein the program voltage applied to the string selection line is incrementally increased.

6. The method of claim 4, wherein the first voltage is a voltage for program inhibiting the string selection transistor, and the second voltage is a voltage for programming the string selection transistor.

7. The method of claim 3, wherein programming of the ground selection transistor comprises:
applying a pass voltage to a word line and a string selection line;
applying a common source line voltage to a common source line;
applying a bit line voltage to a bit line; and
applying a program voltage to a ground selection line,
wherein the bit line voltage comprises a third voltage when the ground selection transistor is programmed and a fourth voltage when the ground selection transistor is not programmed.

8. The method of claim 7, wherein the program voltage is incrementally increased.

9. The method of claim 7, wherein the common source line voltage is incrementally increased.

10. The method of claim 9, wherein the third voltage is a voltage for program inhibiting the ground selection transistor, and the fourth voltage is a voltage for programming the ground selection transistor.

11. A method of programming a NAND flash memory device, the method comprising:
erasing a selection transistor of a selected memory block;
loading data for programming the selection transistor into a page buffer;
programming the selection transistor through channel hot electron injection; and
programming a selected memory cell through Fowler-Nordheim (F-N) tunneling.

12. The method of claim 11, wherein the selection transistor comprises a charge storage layer.

13. The method of claim 11, wherein erasing the selection transistor is selectively performed.

14. The method of claim 11, wherein erasing the selection transistor comprises:
applying a ground voltage to a word line;
applying a first voltage to a string selection line and a ground selection line; and
applying an erase voltage to a bulk.

15. The method of claim 14, wherein the first voltage is a voltage for inhibiting the selection transistor from being over erased.

16. A memory system comprising:
a NAND flash memory device; and
a memory controller for controlling the NAND flash memory device, the NAND flash memory device comprising:
a cell string including a plurality of series-connected memory cells; and
a selection transistor connected in series to the cell string and having the same structure as a memory cell of the plurality of series-connected memory cells, wherein the selection transistor is programmed through channel hot electron injection.

17. The memory system of claim 16, wherein the NAND flash memory device and the memory controller are integrated into one memory card.

18. A method of programming a non-volatile memory device, the method comprising:
programming a selection transistor through channel hot electron injection; and
programming a selected memory cell through Fowler-Nordheim (F-N) tunneling.

19. The method of claim 18, wherein the selection transistor comprises a charge storage layer.

20. The method of claim 18, wherein the non-volatile memory device comprises a NOR memory device including a memory cell, the memory cell being programmed through F-N tunneling.
